(19) United States
(12) Patent Application Publication
(10) Pub. No.: US 2013/0270407 A1
(43) Pub. Date: Oct. 17, 2013

(54) Universal Mount System For A Monitor

(71) Applicant: Sung I. Oh, West Covina, CA (US)

(72) Inventor: Sung I. Oh, West Covina, CA (US)

(21) Appl. No.: 13/457,197

(22) Filed: Apr. 26, 2012

Related U.S. Application Data
(60) Provisional application No. 61/622,703, filed on Apr. 11, 2012.

(51) Int. Cl. H05K 7/00; B32B 38/04

(52) U.S. Cl. 248/220.22; 156/253

(57) ABSTRACT

A mount system is adapted to attach a monitor to a wall. The mount system includes a panel mounting bracket with a flexible member between two bars. Each bar has a plurality of holes such that matching holes between two bars are separated to substantially match different distances between the top two VESA holes on the rear side of monitors. This way, the panel mounting bracket can universally fit different monitors. The mount system also includes a wall plate with a “U” shape hook adapted to receive the flexible member. The flexible member is bonded to the two bars in such a way to substantially prevent the flexible member from disengaging from the two bars due to the weight of the monitor.

### BACKGROUND OF THE INVENTION

1. Field of the Invention

This invention is directed a mount system that attaches a monitor to a wall, and in particular, hangs the monitor to a wall.

2. Background of the Invention

Flat panel monitors such as computer monitors, LCD, plasma, slim televisions, and the like (collectively referred to as “monitor(s)”) are becoming popular because they can be mounted onto a wall to save floor space and for their aesthetically pleasing appearance. In particular, monitors are generally mounted to a wall with a mechanical support arm or a bracket, and then fixed in a desired orientation to maximize the viewing angle of the monitor.

One of the mounts is a wire type mount that hangs a monitor to a wall. This type of a mount has a wire with both ends of the wire having a washer. Most monitors provide four threaded holes on the back side arranged in either square or rectangular configuration. The two washers are screwed on to the top two threaded holes on the back of the monitor. Two wall hooks are also provided and when they are attached to a wall, the monitor is lifted and lowered until the two wall hooks latches on to the wire. This allows the monitor to be hung on the wall much like a picture frame.

One of the disadvantages with the wire type mounts being offered today is that they are only design to fit one type of hole pattern on the back side of the monitor. In general, monitors are generally provided standard holes patterns generally referred to as VESA holes on the rear side of the monitor. VESA holes on the rear side of the monitor generally provides four threaded holes in a square or rectangular configuration with one of the following width and vertical hole patterns: 75 mm (width)×75 mm (vertical); 1.00 mm×100 mm; 200 mm×200 mm; 300 mm×300 mm; 400 mm×400 mm; and 600 mm×400 mm. For instance, the wire type wire mount offered today has a fixed distance between the two washers, when the wire is straight, designed to fit one of the hole patterns such as 300 mm×300 mm, but it will not fit the other hole patterns.

Another disadvantage is that the weight of the monitor can apply high tensile or pulling force on the wire such that the wire may disengage from the washer causing the monitor to drop to the floor. As such, there still is a need for a wire type mount that is universal so that it can fit different types of hole patterns and be able to securely engage the wire to the washer.

### INVENTION SUMMARY

This invention is directed to a mount system adapted to couple a monitor to a supporting surface such as a side wall. The mount system includes a panel mounting bracket with a flexible member between two bars. Each bar has a plurality of holes such that corresponding holes between two bars are separated to substantially match different distances between the top two VESA holes on the rear side of monitors. This allows the panel mounting bracket to universally fit monitors with different VESA hole patterns. The mount system also includes a wall plate adapted to latch onto the flexible member. The flexible member has a washer bonded to both ends. Each bar has a rigid member where one end of the rigid. member is adapted to couple the washer. To substantially prevent the rigid member from bending, the rigid member may have double layers of housing. In this regard, a mount system includes: a panel mounting bracket having: a flexible member between a first washer and a second washer, each of the first and second washers having an opening; a first rigid member having a first end and a second end, the first end of the first rigid member adapted to couple to the first washer, the first rigid member having a plurality of holes between the first and second ends; a second rigid member having a first end and a second end, the first end of the second rigid member adapted to couple to the second washer, the second rigid member having a plurality of holes between the first and second ends of the second rigid member; and a wall plate adapted to couple to the wall, the wall plate having a hook adapted. to receive flexible member.

Other systems, methods, features, and advantages of the invention will be, or will become, apparent to one with skill in the art upon examination of the following figures and detailed description. Ti: is intended that all such additional systems, methods, features, and advantages be included within this description, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 shows a perspective view of a mount system.

FIG. 2 shows a perspective view of a wire having a plurality of washers with pods.

FIG. 3 shows a perspective view of the wire with the plurality of washers without the pods.

FIG. 4 shows an exploded view of a pod.

FIG. 5 shows side view of a wall bracket.

FIG. 6 shows a perspective view of the wall bracket of FIG. 5.

FIG. 7 shows the wall bracket without the enclosure showing a hook bracket.

FIG. 8 shows a rear perspective view of the hook bracket.

FIG. 9 shows another perspective view of the enclosure two tabs removed.

FIG. 10 shows a perspective of a pod.

FIG. 11 shows a top view of the mount system and a monitor.

FIG. 12 shows a side view of the mount system with spacers between the pods and the rear side and the monitor.

FIG. 13 shows a spacer.

FIG. 14 shows a perspective view of another mount system.

FIG. 15 shows another perspective view of the mount system with the housing on one of the elongated bars removed.

FIG. 16 shows a rear perspective view of the mount system of FIG. 14.

FIG. 17 shows a side view of the mount system of FIG. 14.

FIG. 18 shows a panel mounting bracket with a wire between two rigid members.

FIG. 19 shows the wire weaving through the rigid members.

FIG. 20 shows another panel mounting bracket having a wire between two washers where the washers are adapted to couple a rigid member.

FIG. 21 shows a perspective view of a washer.

FIG. 22 shows a top view of the washer.

FIG. 23 shows another view of the washer.

FIG. 24 shows a perspective view of another rigid member adapted to couple to a washer.

FIG. 25 shows a washer coupled to a rigid member.

FIG. 26 shows a close up view of the opposite side of the washer of FIG. 25.

FIG. 27 shows a top view of the panel mounting bracket of FIG. 20.

FIG. 28 shows an inner housing of one of the bars.

FIG. 29 shows a perspective view of the inner housing of FIG. 28.

FIG. 30 shows an outer housing molded over the inner housing on one of the bars.

### DETAILED DESCRIPTION OF THE INVENTION

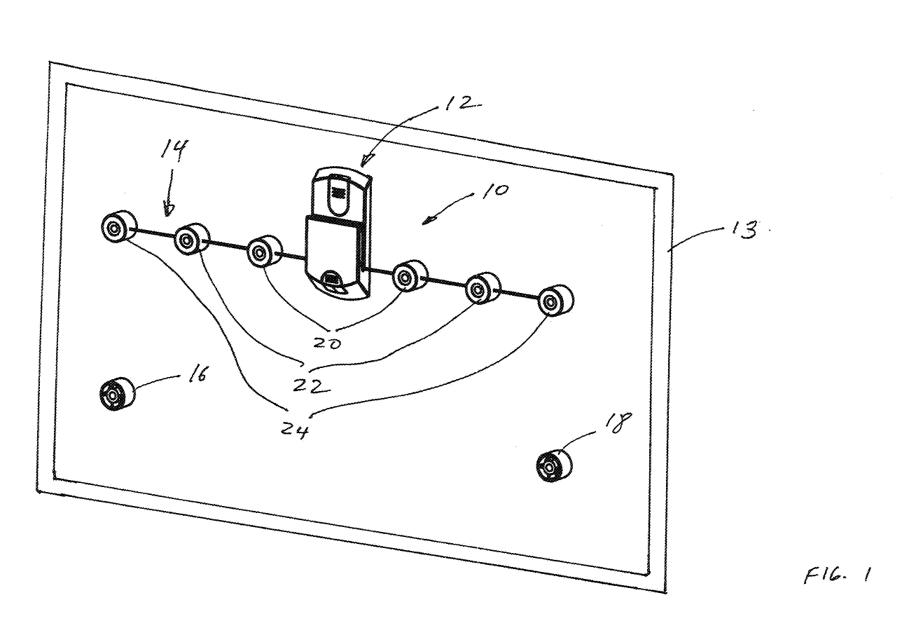

FIG. 1 shows a front perspective view of a mount system 10 adapted to hang a monitor 13 onto a wall. The mount system 10 includes a wall bracket 12 adapted to attach to a wall, a universal wire 14, and bottom spacers 16 and 18. The universal wire 14 may have at least one pair of pods 20, 22, and 24. In this example, the universal wire 14 may have at least two pair of pods.

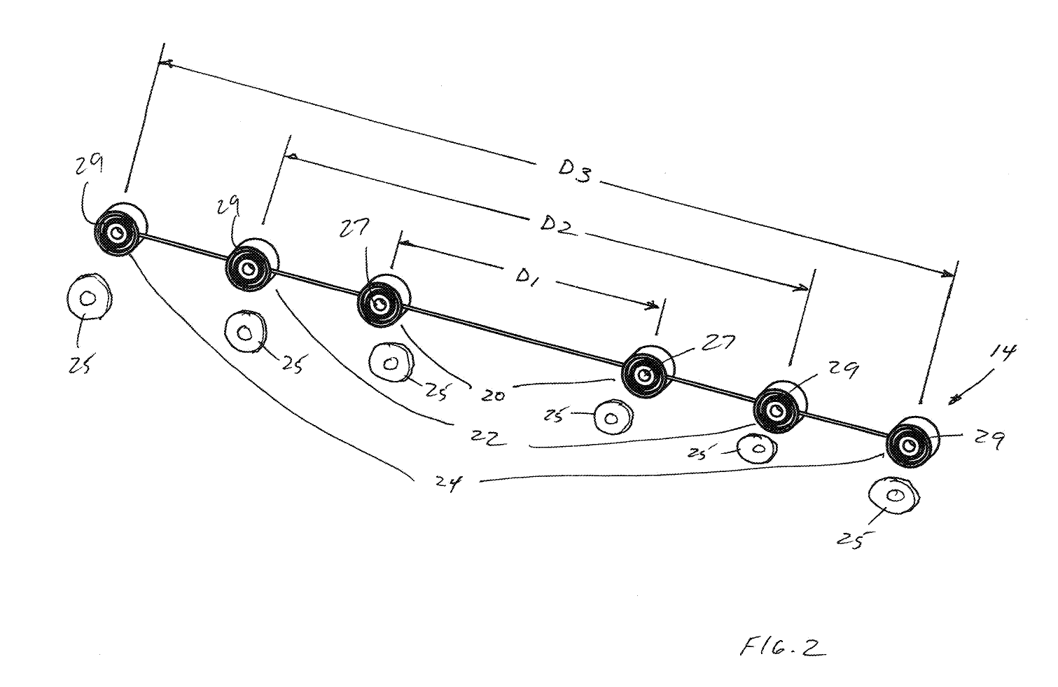

FIG. 2 shows a front perspective view of the universal wire 14. The first pair of pods 20 may be distance D1 apart; the second pair of pods 22 may be distance D2 apart; and the third pair of pods 24 may be distance D3 apart. As an example, the distance D1 may be 200 mm; the distance D2 may be 400 mm; and the distance D3 may be 600 mm. As an example, if the monitor 13 is provided with 100 mm×100 mm or 200 mm×200 mm hole pattern on the back side of the monitor, then the first pair of pods 20 may be used to attach the universal wire 14 to the back side of the monitor; if the monitor 13 is provided with 300 mm×300 mm or 400 mm×400 mm hole pattern on the back side of the monitor, then the second pair of pods 22 may be used to attach the universal wire to the back side of the monitor; and if the monitor 13 is provided with 500 mm×400 min or 600 mm×400 mm hole pattern on the back side of the monitor, then the third pair of pods 24 may be used to attach the universal wire 14 to the back side of the monitor 13. As such, the universal wire 14 may accommodate a variety of different hole patterns on the back of the monitor.

FIG. 2 also shows that each pod may be provided with a releasable double sided tape 25. When the universal wire 14 is in use, one pair of pods may be used, which means that the other two pair of pods are not in use or free. For instance, if the monitor has a 200×200 hole pattern, the first pair of pods 20 may be used to insert a screw through the each of the openings 27 and secured to the threaded opening on the back of the monitor. This means that the second and third pair of pods 22 and 24 are not in use. The double sided tape 25 may be applied to a first end 29 of the pods 22 and 24, and these pods may be applied or adhered to the back side of the monitor 13. For instance, the second and third pair of pods 22 and 24 maybe applied in a straight line as shown in FIG. 1 so that the universal wire 14 is substantially along the longitudinal axis of the monitor 13. In reference to FIG. 1, this allows the second and third pair of pods 22 and 24 to extend out and lean against the wall to stabilize the monitor 13, thus minimizing the monitor 13 from wobbling relative to the wall.

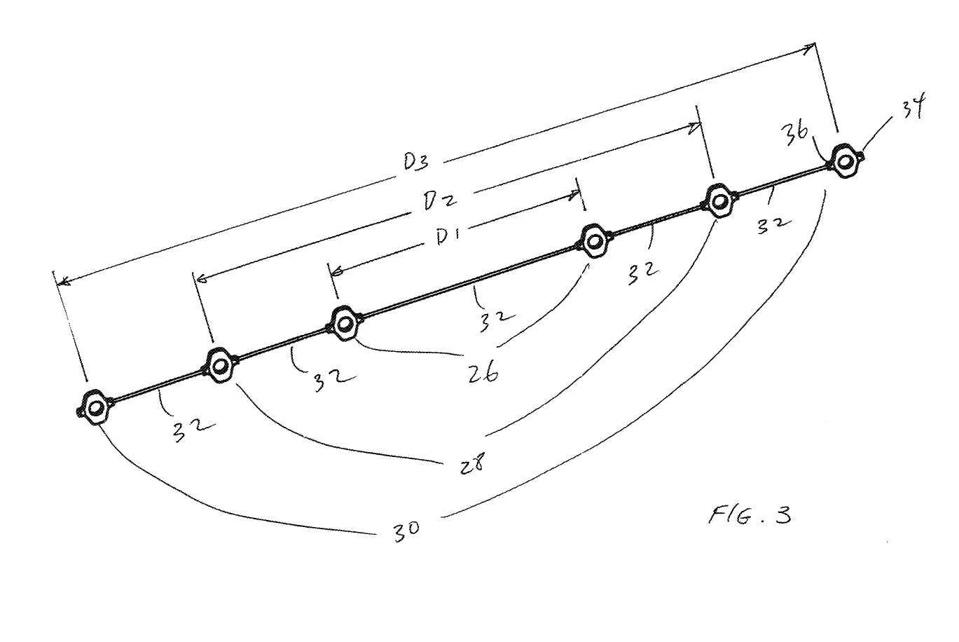

FIG. 3 shows the universal wire 14 without the pods 20, 22, and 24. The universal wire 14 may include at least one pair of washers 26, 28, and 30. The first pair of washers 26 may be distance D1 apart; the second pair of washers 28 may be distance D2 apart; and the third pair of washer 30 may be distance D3 apart corresponding to their respective pair of pods 20, 22, and 24. Each washer may be coupled together by a wire 32 to space each of the pair of washers at the desired lengths D1, D2, and D3, as discussed above when the wires 32 are straight. Each washer may have a first end 34 and a second end 36 that couples to the wire 32 to form a chain of washers with a wire 32 between two adjacent washers. One end of the wire 32 may be coupled to the washer through a variety of methods and mechanisms. For instance, the end 36 of the washer 30 maybe clamped, screwed, or welded onto the second end 36 of the wire 32.

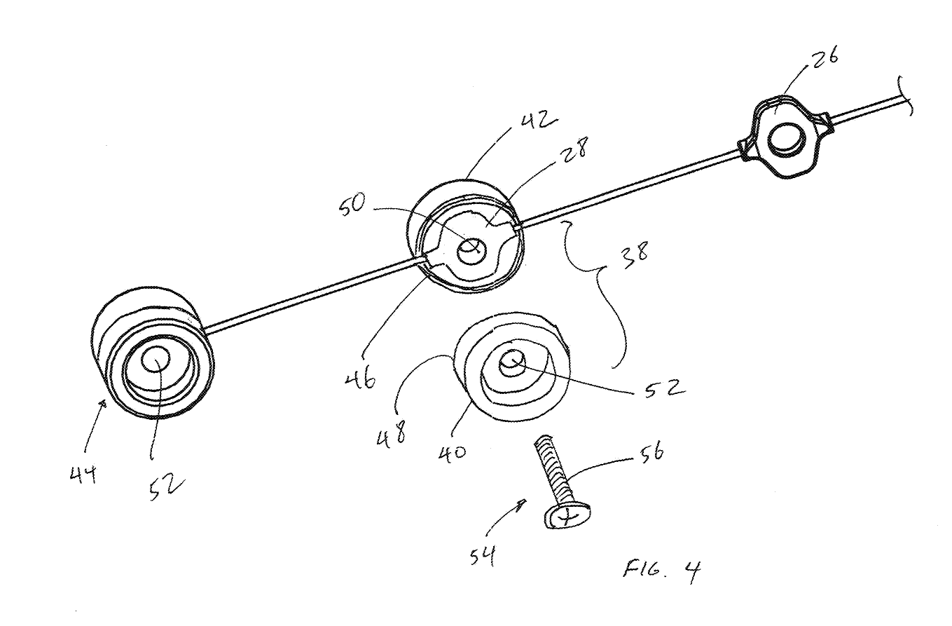

The pair of pods 20, 22, and 24 may be formed over their respective pair of washers 26, 28, and 30 through a variety of methods and mechanism. For instance, each pod may be molded over the washer or injection molded over the washer so that they form a unitary piece. Alternatively, FIG. 4 shows that a pod 38 may include a first portion 40 and a second portion 42. The second portion 42 may be adapted to receive a washer 28, and the first and second portions 40 and 42 may sandwich the washer 28 together as illustrated by a pod 44. The first and second portions 40 and 42 may be coupled together through a variety of methods and mechanisms such as being screwed together, glued together. For instance, the second portion 42 may have a threaded end 46, and the first portion 40 may have a matching threaded end 48 adapted to engage with the threaded end 46 so that the first portion 40 may be rotated onto the second portion 42 much like a screw and a bolt. The diameter of a hole 50 within the washer 28 may be same as the diameter of a hole 52 within the first portion 40 so that when a screw 54 is inserted through the 52 of the pod 44, the threaded portion 56 of the screw 54 may engage with the opening 50 of the washer 28 to securely engage the washer 28 to the back side of the monitor and support the weight of the monitor.

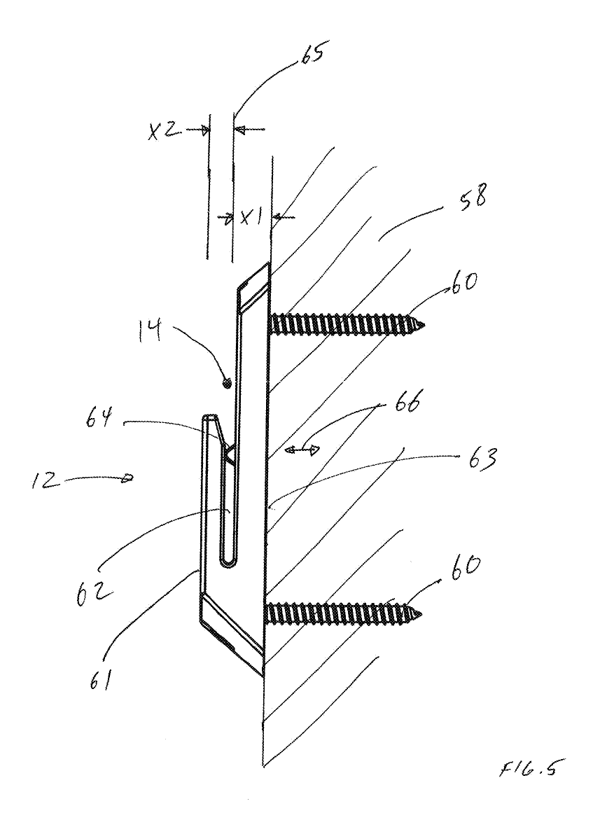

FIG. 5 shows side view of the wall bracket 12 adapted to anchor to a wall 58 with screws 60. The wall bracket 12 may have a cavity 62 adapted to receive the universal wire 14.

The wall bracket 12 may have a clip 64 adapted to move back and forth as indicated by a direction arrow 66. As the monitor 13 is lifted and then lowered, the universal wire 14 behind the monitor 13 drops into the cavity 62 and pushes the clip 64 towards the wall 58 and once the wire passes the clip 64, the clip moves back to the original position as shown in FIG. 5. The cavity 62 may be deep so that the combination of the deep cavity 62 and the clip 64 may substantially prevent the universal wire 14 from unintentionally disengaging from the wall bracket 12. The wall bracket 12 may have a first side 61 and a second side 63. The reference line 65 may represent a center line of the cavity 62. The distance between the second side 63 and the line 65 may be X1, and the distance between the first side 61 and the line 65 may be X2.

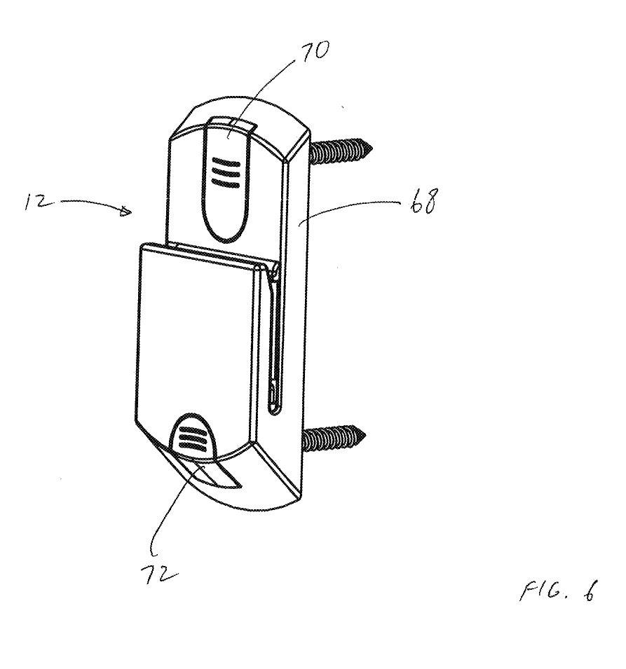

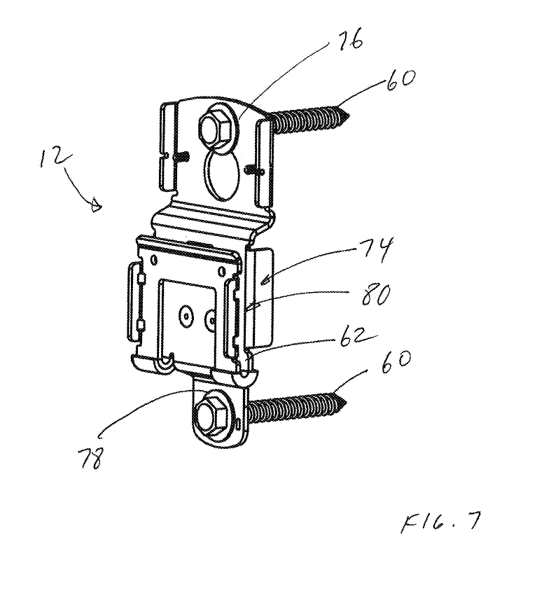

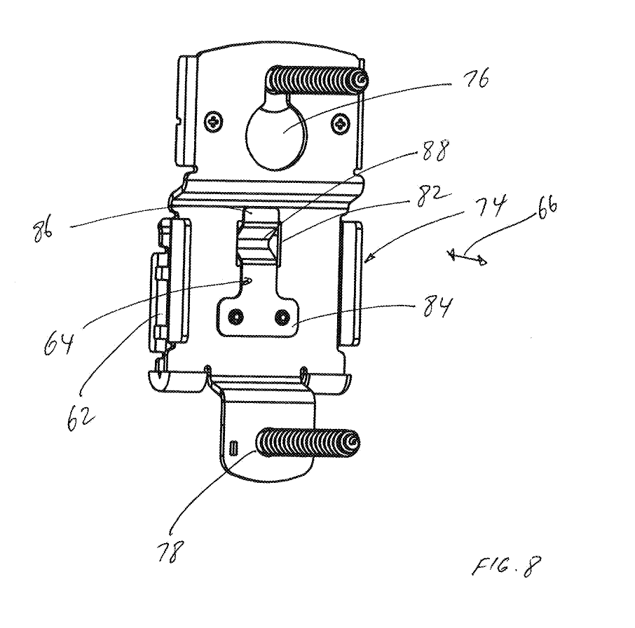

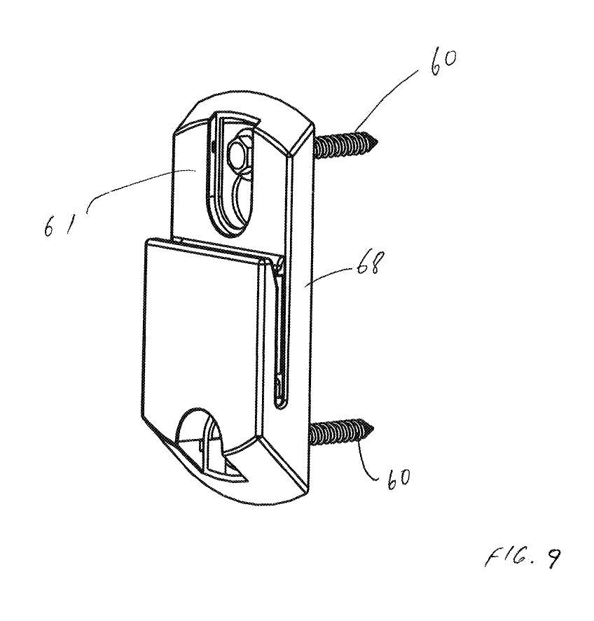

FIG. 6 shows a front perspective view of the wall bracket 12. The wall bracket 12 may have an enclosure 68. The enclosure 68 may be made of a variety of materials such as plastic and the enclosure 68 have a removable first tab 70 and a removable second tab 72. FIG. 7 shows the wall bracket 12 without the enclosure 68 showing a hook bracket 74. The hook bracket 74 may have openings 76 and 78 adapted to receive the screws 60. The hook bracket 74 may be formed to have a hook 80 to form the cavity 62. The hook 80 may be in the form of a U-shape. FIG. 8 shows a rear perspective view of the hook bracket 74 showing an opening 82. The clip 64 may have a first end 84 and a second end 86. The first end 84 may be coupled to the hook bracket 74 and the second end 86 may be free to move along the direction arrow 66. The second end 86 may form a tip 88 to substantially block the universal wire 14 to moving out of the cavity 62. FIG. 9 shows the front perspective view of the enclosure 68 with the first and second tabs 70 and 72 removed. This allows the screws 60 to be inserted through the front side 90 of the enclosure 68.

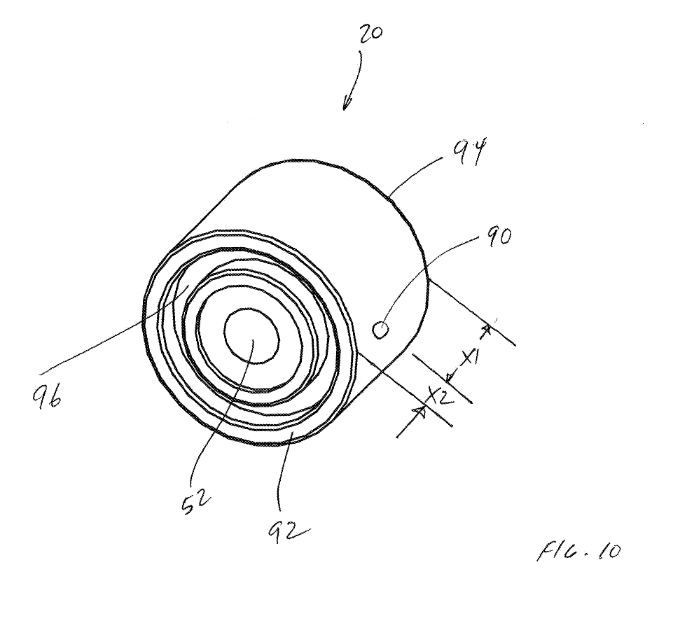

FIG. 10 shows a perspective of a pod 20 having an opening 90 for the universal wire 14. The pod 20 may have a first end 92 and a second end 94. The distance between the second end 94 and the opening 90 may be X1; and the distance between the first end 92 and the opening 90 may be X2. FIG. 10 also shows that the first end 92 may have a cavity 96 adapted to receive a spacer as discussed in more detail below.

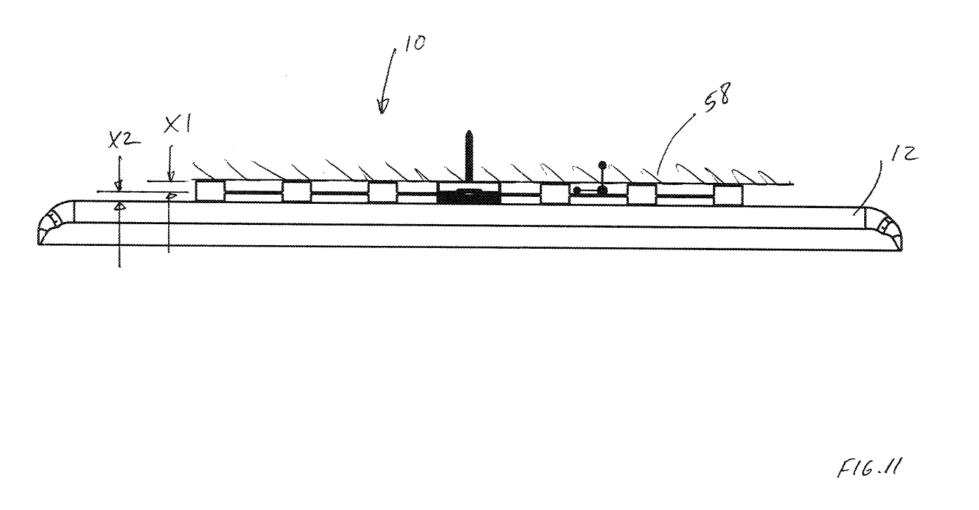

FIG. 11 shows a top view of the mount system 10 and the monitor 13. As discussed above, the location of the cavity 62 may be X1 from the wall 58, and the distance between the second end 94 and the opening 90 of the pods 20, 22, and 24 may be X1 so that as the monitor 13 is lowered, the wire 14 may slide into the cavity 62 without interference. Moreover, the depth of the wall bracket 12 (X1+X2) may be same as the depth of the pods so that the pods arrange in a linear manner as shown in FIG. 11 may stabilize the monitor 12.

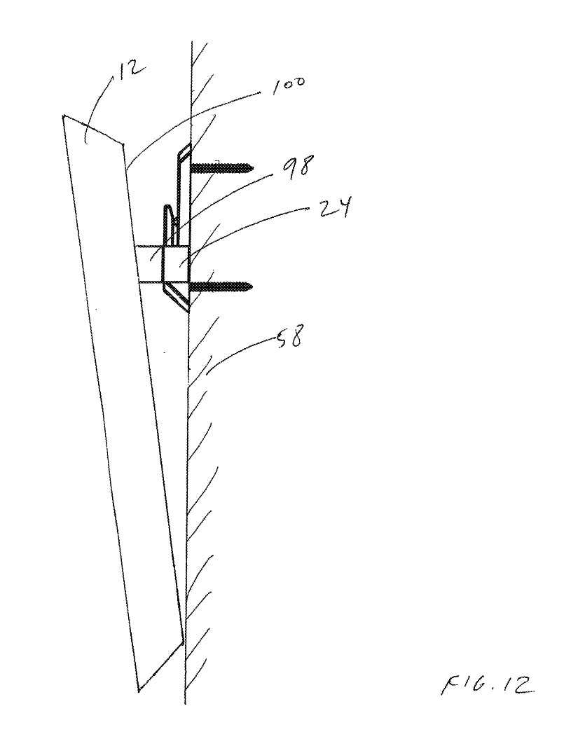

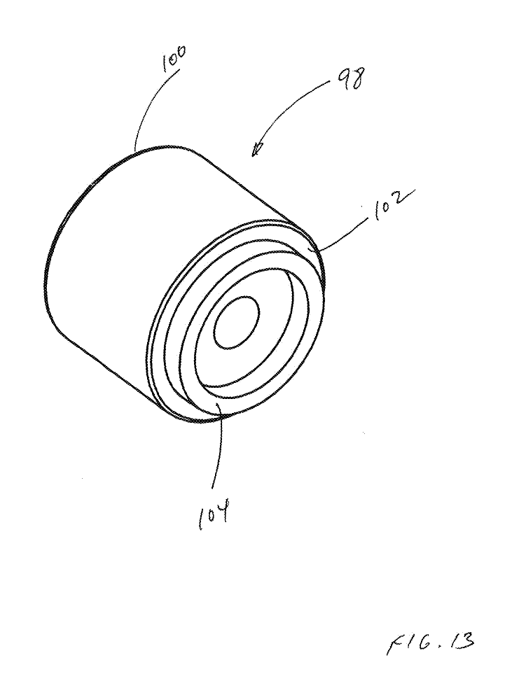

FIG. 12 shows a side view of the mount system 10 with spacers 98 between the pods 24 and the rear side 100 and the monitor 13. The spacers 98 extend the top portion away from the wall 58 farther than the bottom portion, thus tilting the monitor 13 down. FIG. 13 shows the spacer 98 having a first end 100 and a second end 102. The second end 102 may have a protruding tab 104 adapted to engage the cavity 96 of the first end 92 of the pod 20. This allows the spacers and the pods to securely engage with each other.

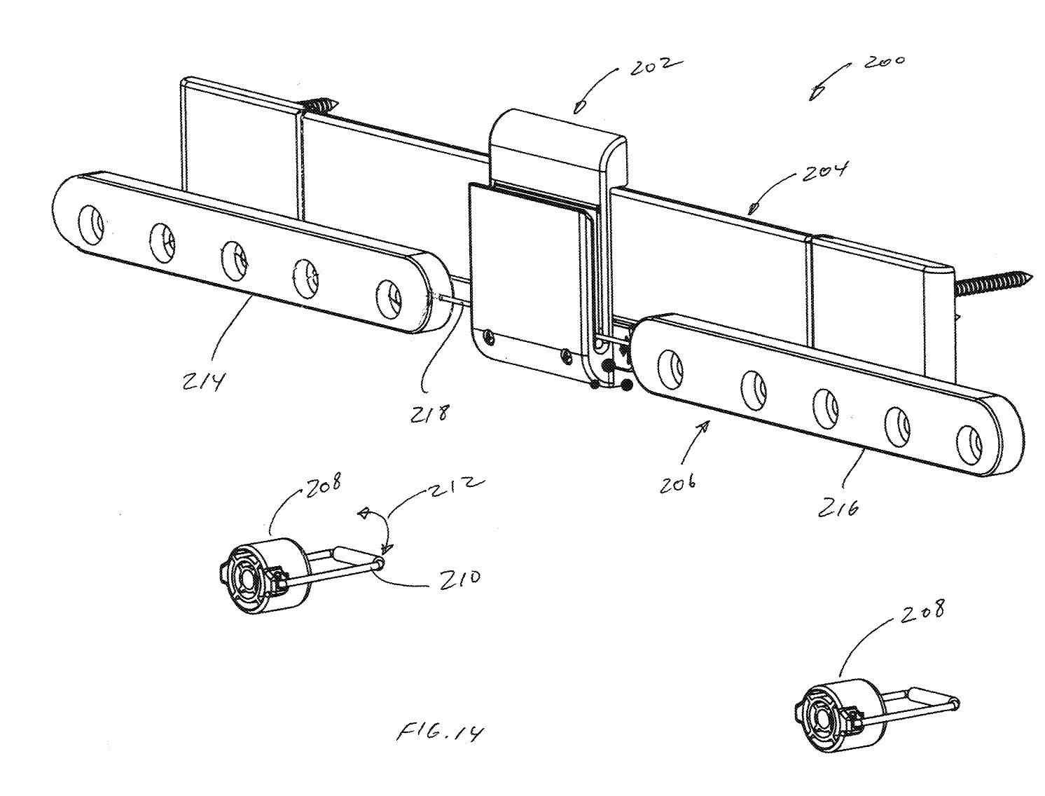

FIG. 14 shows a perspective view of another mount system 200 including a bracket 202 adapted to couple to a wall plate 204, and a panel mounting bracket 206 adapted to couple to a variety of hole patterns on the rear side of the monitor 13 and couple to the bracket 202. The panel mounting bracket 206 may include a first bar 214 and a second bar 216, and a flexible member 218 coupling the two bars 214 and 216 together. The mount system 200 may also include one or more kick stands 208. The kick stand 208 may include a leg 210 that may move in an arcing manner as illustrated by the direction arrow 212 such that when the leg is in an extended position as shown in FIG. 14, the monitor may tilt up to allow a user to have access to the rear side of the monitor.

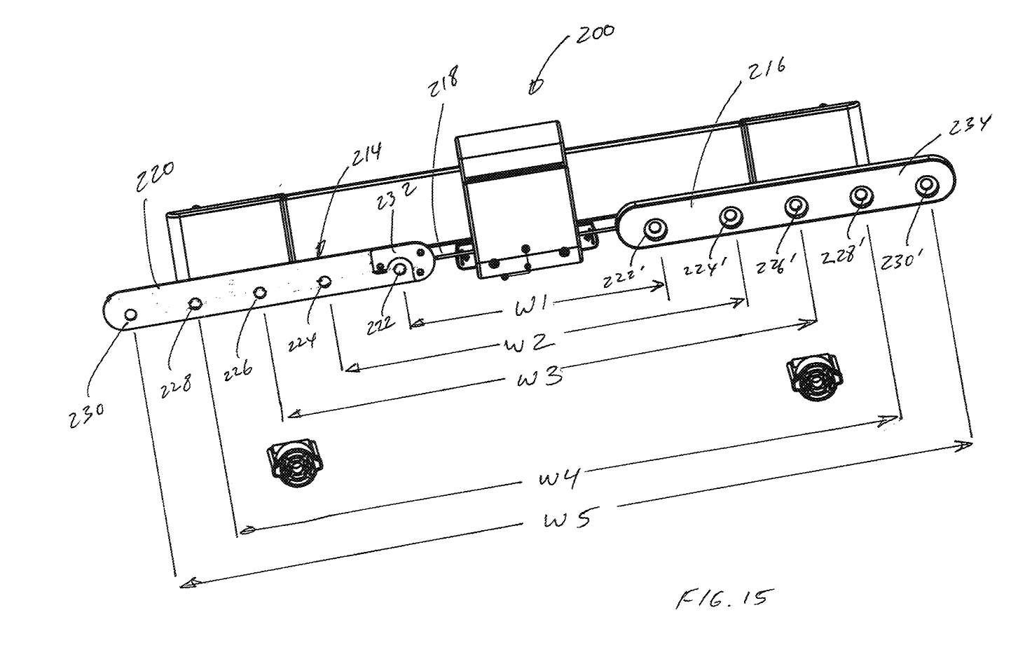

FIG. 15 shows another perspective view of the mount system 200 with the housing on the first bar 214 removed. In general, the first and second bars 214 and 216 may be construed in a substantially similar manner. As such, the descriptions relating to the first bar 214 may apply to the second bar 216, and vice versa. The first bar 214 may include a rigid member 220 having a plurality of holes 222, 224, 226, 228, and 230. The rigid member 220 may be made of a variety of materials such as a metal plate. One end of the rigid member 220 may be coupled to the flexible member 218 using a clamp 232 that binds the flexible member 218 to the rigid member 220 or through any other method known to one skilled in the art. The flexible member may be made of a variety of structures such as a cable, wire, and rope. The rigid member may be enclosed with a housing 234 to form a shell as shown by the second bar 216. The housing 234 may be formed from a variety of materials such as an encapsulated plastic around the rigid bar such that the first bar substantially resists bending.

The second bar 216 may have a plurality of holes 222′, 224′, 226′, 228′, and 230′. The length of the flexible member 218 between the two bars 214 and 216 may be such that the distance W1 between the two holes 222 and 222′ may be about 200 mm; the distance W2 between the two holes 224 and 224′ may be about 300 mm; the distance W3 between the two holes 226 and 226′ may be about 400 mm; the distance W4 between the two holes 228 and 228′ may be about 500 mm; and the distance W5 between the two holes 230 and 230′ may be about 600 mm. With a plurality pair of holes separated by distances W1, W2, W3, W4, and W5, the panel mounting bracket 206 may accommodate a variety of different hole patterns on the back of the monitor.

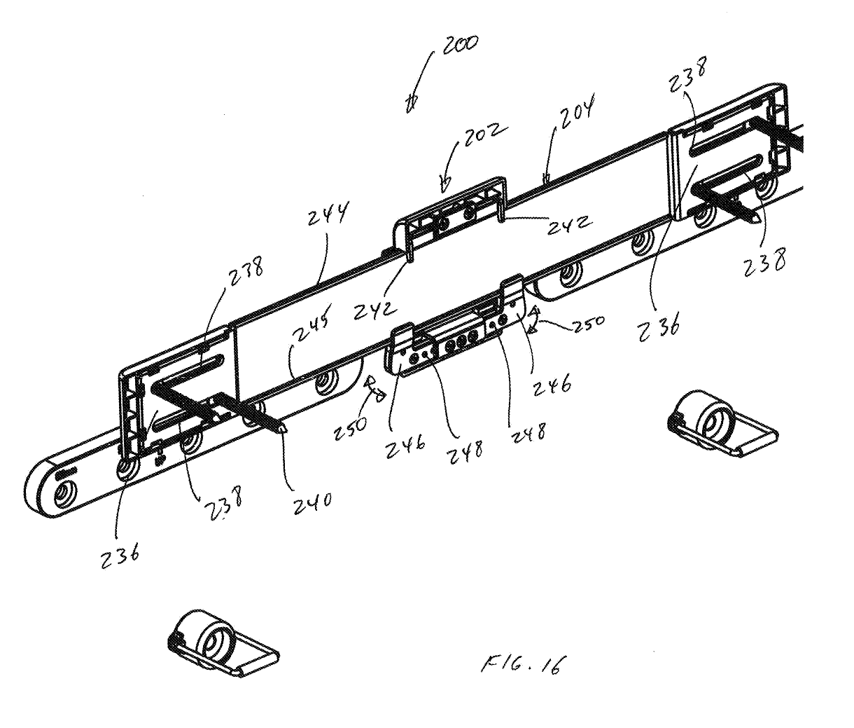

FIG. 16 shows a rear perspective view of the mount system 200. The wall plate 204 may have both ends 236 with elongated openings 238. Each of the openings 238 may be adapted to receive a bolt 240 to couple the wall plate 204 to a wall. The bracket 202 may have one or more teeth 242 adapted to latch over a top rail 244 of the wall plate 204. The bracket 202 may have one or more latches 246 adapted to rotate about their respective pivot axis 248 such that each of the latches may rotate as illustrated by their respective direction arrows 250 in an arcing manner to latch onto to the bottom rail 245 of the wall plate 204. FIG. 16 shows the latches 246 in a locking position so that the bracket 202 may not be released from the wall plate 204. When the bracket 202 is in the locking position, the bracket 202 may slide along the longitudinal axis of the wall plate 204, which allows the monitor 13 to be centered within a room by sliding laterally.

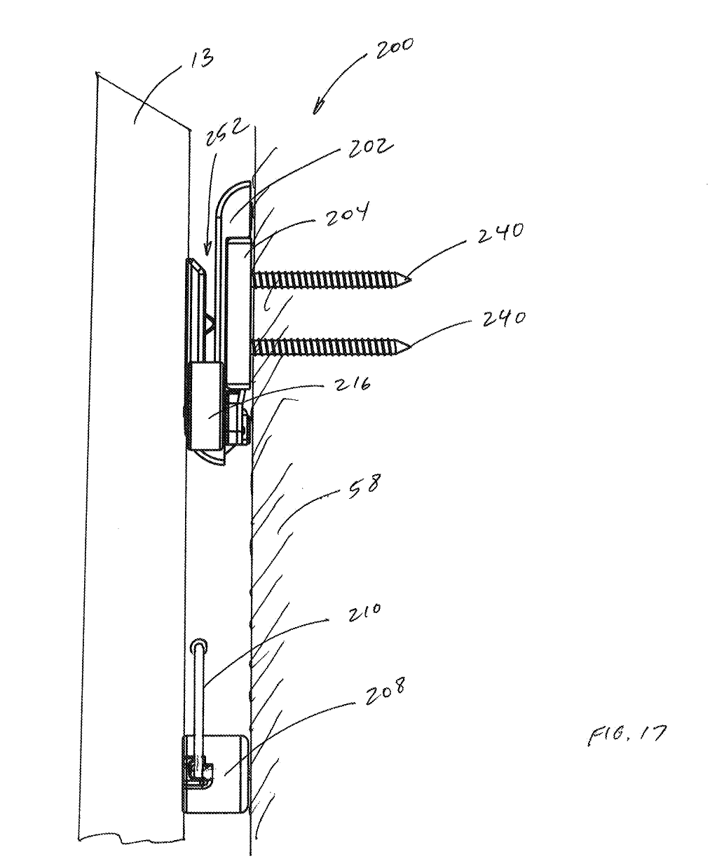

FIG. 17 shows side view of the mount system 200 with the wall plate 204 coupled to a wall 58 with screws 240. The bracket 202 may have a cavity 252 adapted to receive the flexible member 218. Once the panel mounting bracket 206 is coupled to the rear side of the monitor 13, the monitor 13 may be lifted and then lowered so that the flexible member 218 inserts into the cavity 252 of the bracket 202. FIG. 17 also shows the leg 210 in a retracted position so that the monitor 13 may be flush relative to the wall 58.

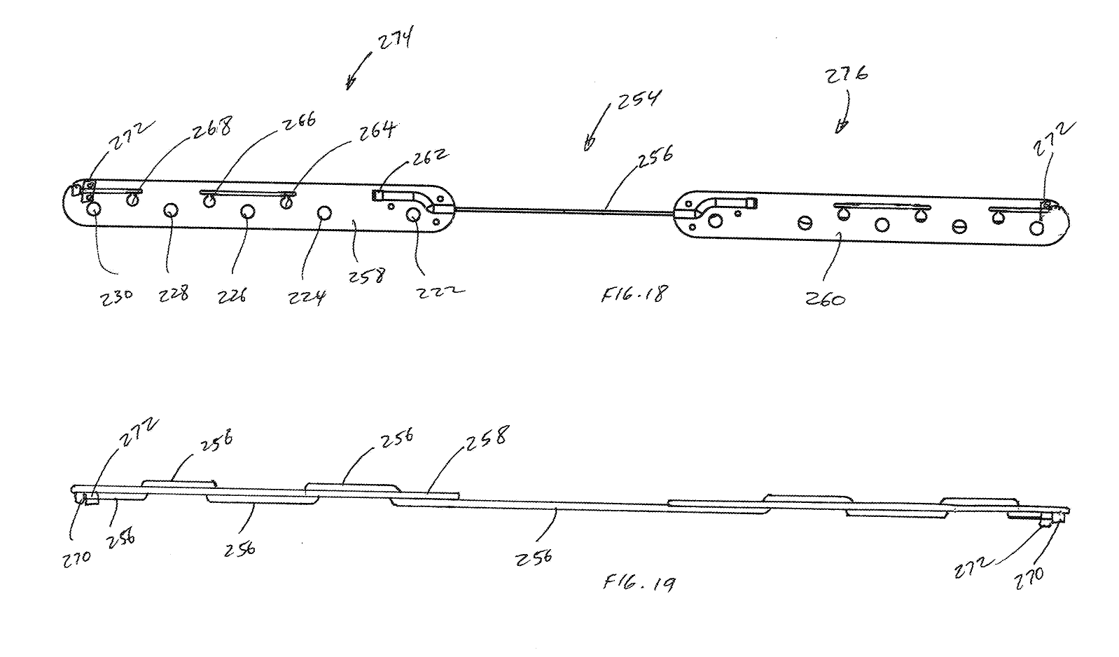

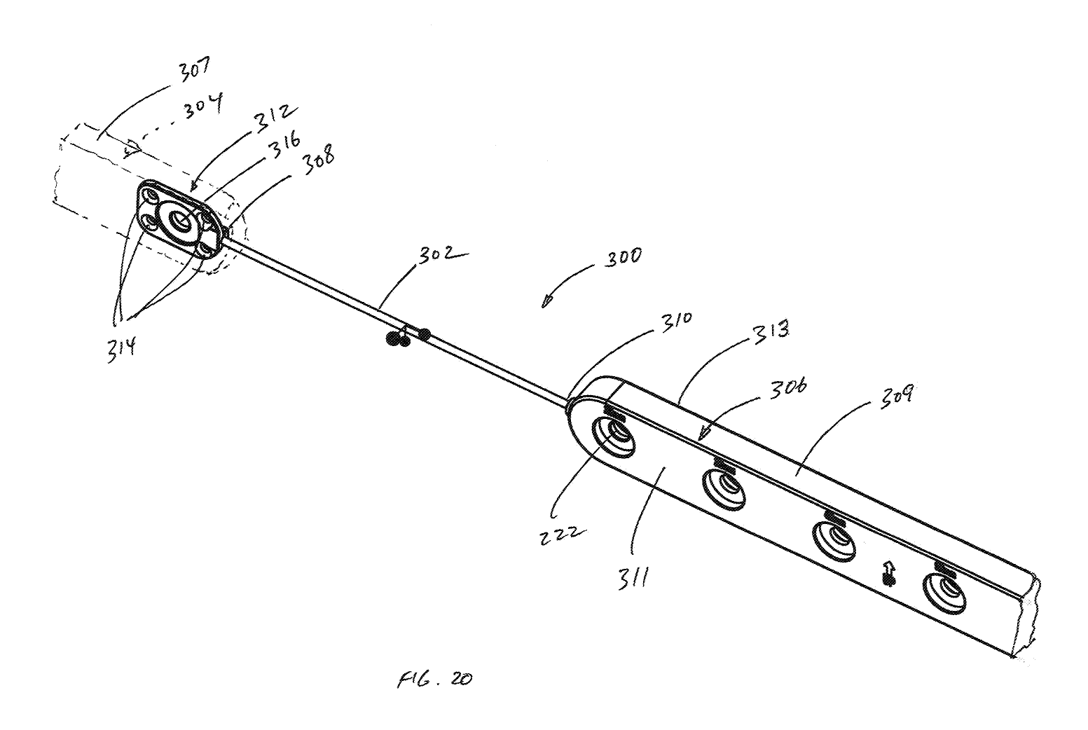

FIG. 18 shows another panel mounting bracket 254 having a flexible member 256 extending along the longitudinal axes of a first rigid member 258 and a second rigid member 260. The first rigid member 258 may have a plurality of holes 222-230, as discussed above. The first rigid member 258 may also have holes 262, 264, 266, and 268. FIG. 19 shows a top view of the panel mounting bracket 254 without the housing. FIG. 19 shows the flexible member 256 weaving through the holes 262, 264, 266, and 268 acting as a backbone to the first bar 274. Each end of the flexible member may have an end ball joint 270 where a second clamp 272 may be used to secure the end ball joint 270 to the rigid member 258. With the flexible member 256 weaving through the first and second rigid members 258 and 260, even if the rigid member breaks clue to fatigue, the flexible member 256 does not break clue to its flexibility so that the first and second bars 274 and 276 may support the weight of the monitor 13.

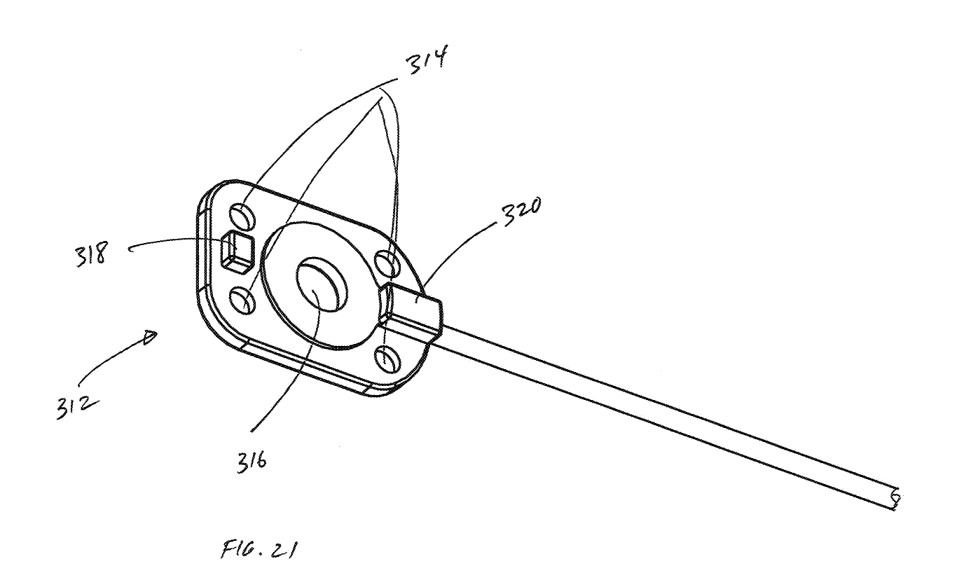

FIG. 20 shows another panel mounting bracket 300 having a flexible member 302 extending along the longitudinal axes of a first bar 304 and a second bar 306. For illustrative purpose, the housing 307 of the first bar is removed, and the housing 309 of the second bar 306 is shown. In general, the first and second bars 214 and 216 may be construed in a substantially similar manner. As such, the descriptions relating to the first bar 304 may apply to the second bar 306, and vice versa. The second bar 306 has a first side 311 and a second side 313, which is opposite of the first side 311. The flexible member 302 may have a first end 308 and a second end 310. Each of the first. and second ends 308 and 310 may be coupled to a washer 312. The washer 312 may have one or more holes 314 adapted to receive a screw. The washer 312 may also have an opening 316 representing the hole 222 of the VESA hole pattern in the panel mounting bracket 300.

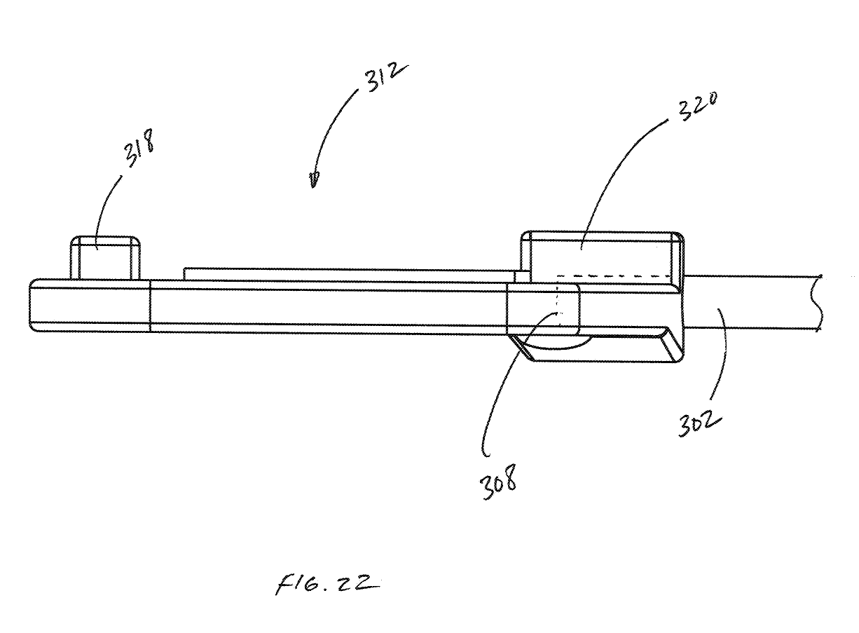

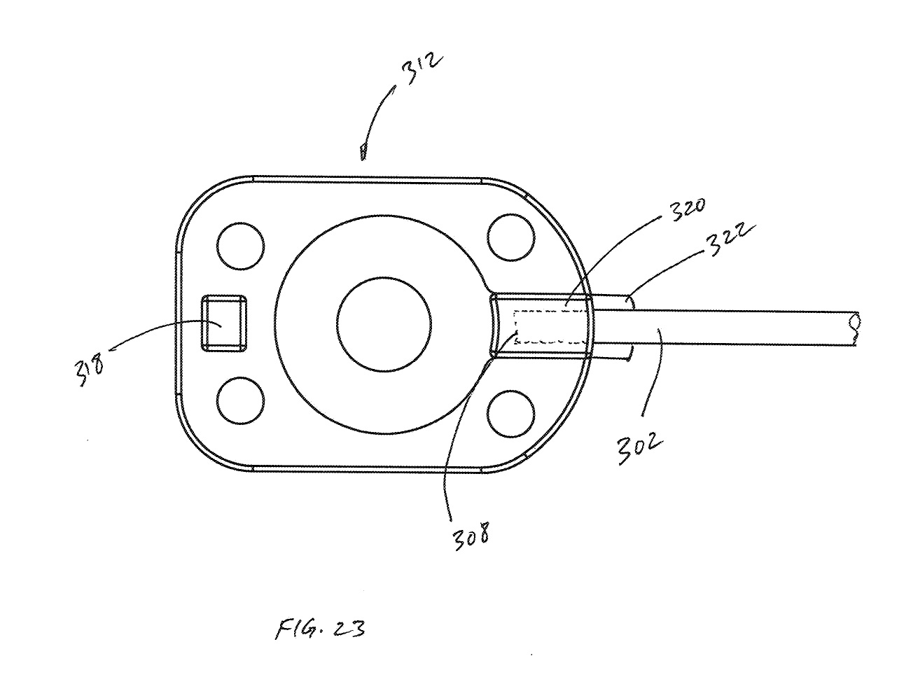

FIG. 21 shows an opposite side view of the washer 312 shown in FIG. 20. The washer 312 may have a protruding member 318 and a bonding area 320. FIG. 22 shows a top view of the washer 312 showing the bonding area 320 encapsulating the first end 308 of the flexible member 302 to securely couple the first end 308 of the flexible member 302 to the washer 312. The washer 312 may be molded over the first end 308 of the flexible member 302 by placing the first end 308 into a mold, and molten zinc may be injected into the mold to form the washer 312 thereby bonding the first end 308 into the bonding area 320 of the washer. FIG. 23 shows that the bonding area 320 may be extended to form a tab 322 to cover more surface area of the first end 308 of the flexible member 302 to provide a stronger bond between the washer 312 and the flexible member 302.

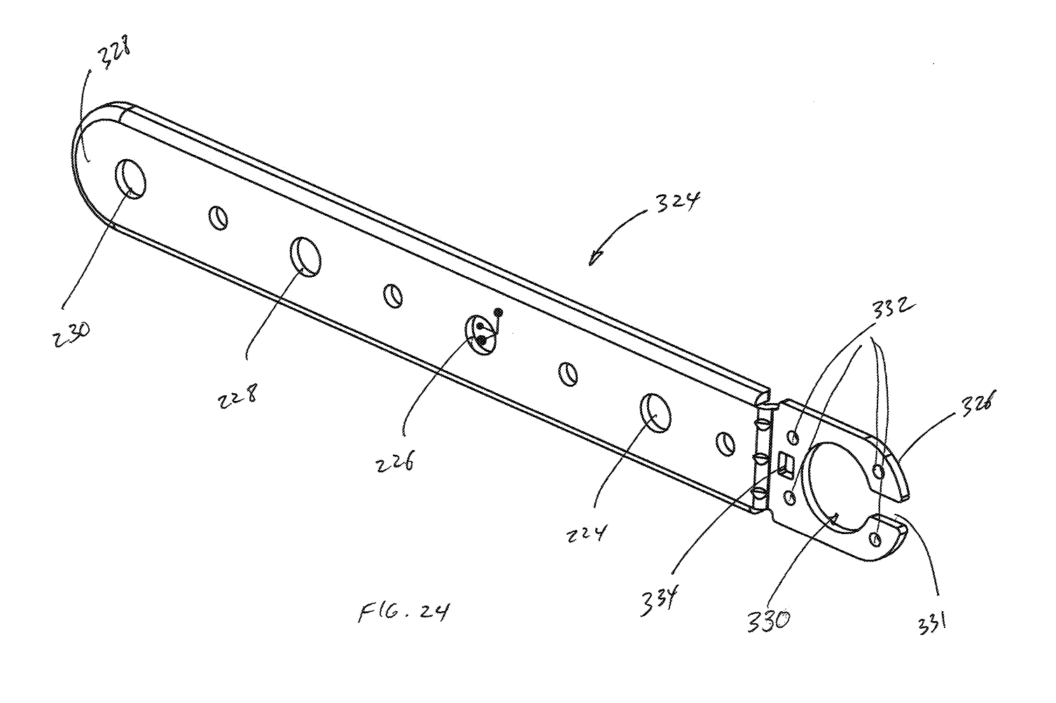

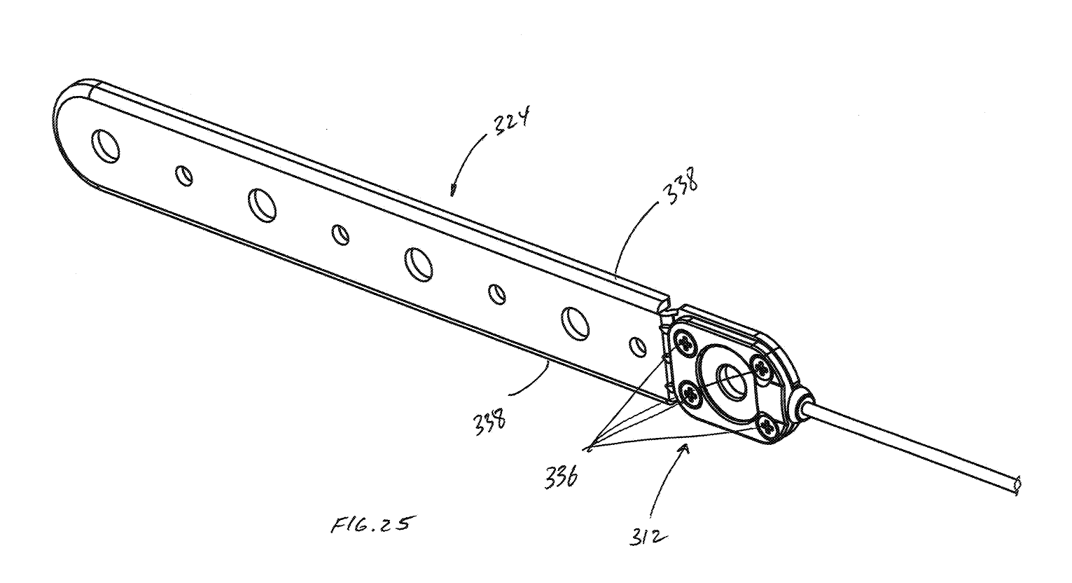

FIG. 24 shows that the first bar includes a first rigid member 324 having a plurality of holes 224-230, as discussed above. The first rigid member 324 may have a first end 326 and a second end 328. The first end 326 may have a key hole 330 adapted to couple to the washer 312. The key hole 330 may have an open slot 331 adapted to receive the bonding area 320. The first end 326 may also have holes 332 adapted to align with the holes 314 on the washer 312. The holes 332 may be treaded adapted to receive screws. The first end 326 may also have an opening 334 adapted to receive the protruding member 318 to hook the washer onto the first rigid member 324 such that as the flexible member pulls on the first rigid member 324, the washer latched onto the rigid member 324.

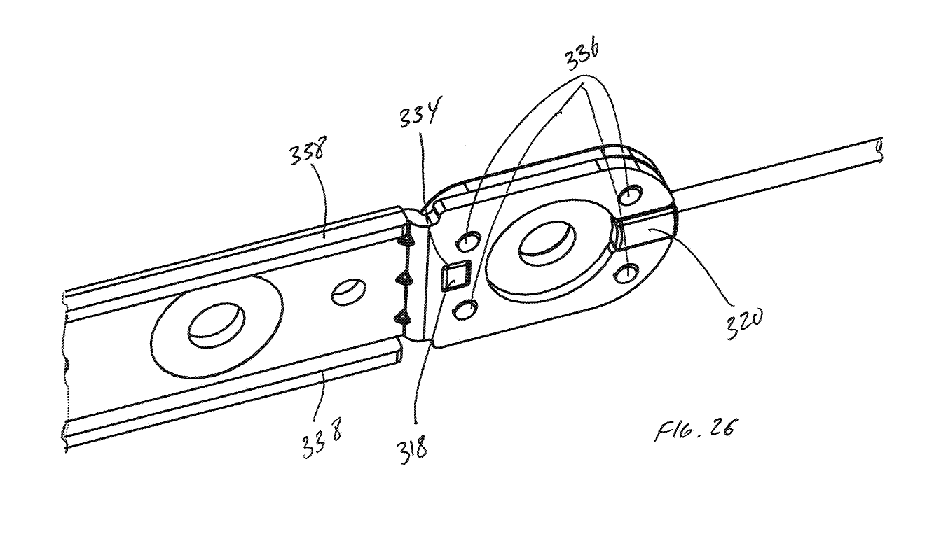

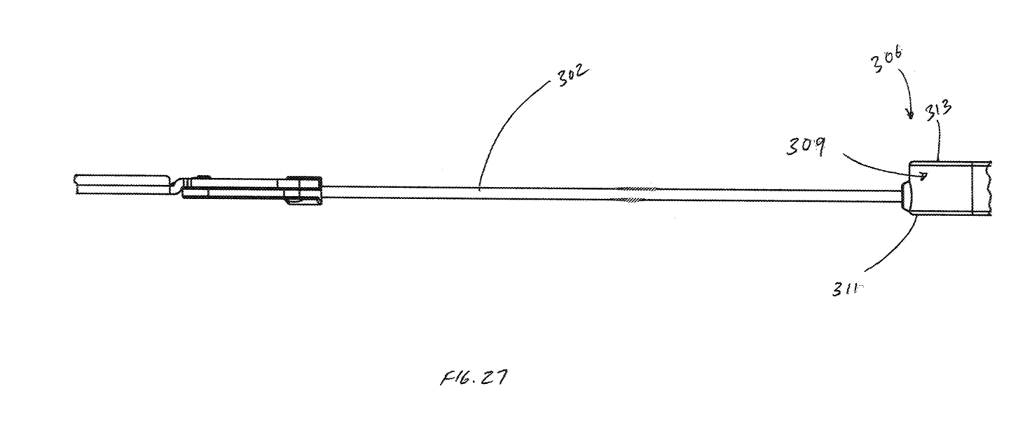

FIG. 25 shows the washer 312 coupled to the first rigid member 324 by tightening screws 336 into the holes 314 of the washer and threaded holes 332 of the first rigid member 324. The first ridge member 324 may have flanges 338 to substantially minimize the first rigid member 324 from bending. FIG. 26 shows the opposite side of the washer 312 coupled to the first rigid member 324 of FIG. 25. FIG. 26 shows the protruding member 318 inserted into the opening 334 to latch into the first rigid member.

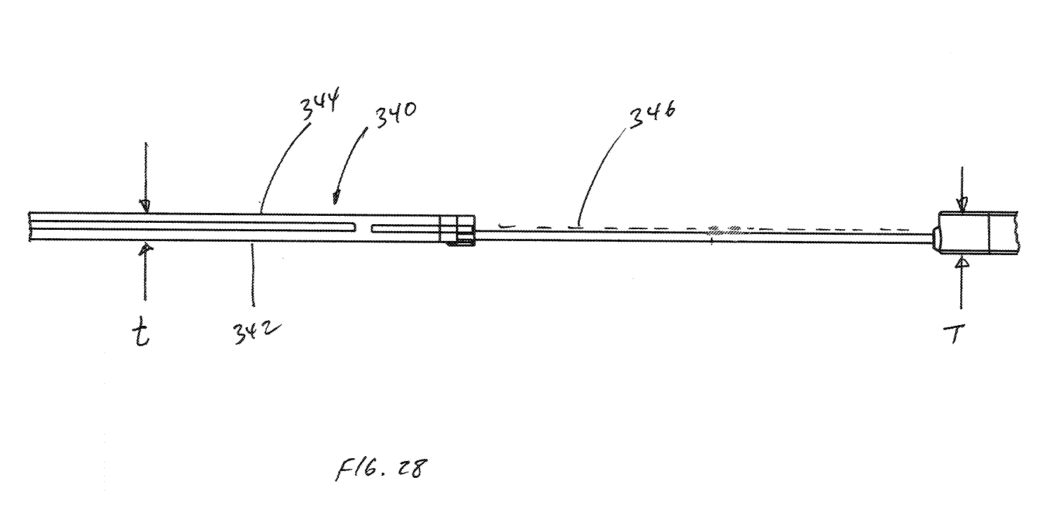

FIG. 27 shows a top view of the panel mounting bracket 300. The second bar 306 illustrates that the flexible member 302 may be offset such that the longitudinal axis of the flexible member 302 may be closer to a first side 311 of the housing 309 than the second side 313. To minimize the first and second bars 304 and 306 from bending during the molding process of the housing 304 over the first rigid member 324, the housing 304 may be formed in more than one stage.

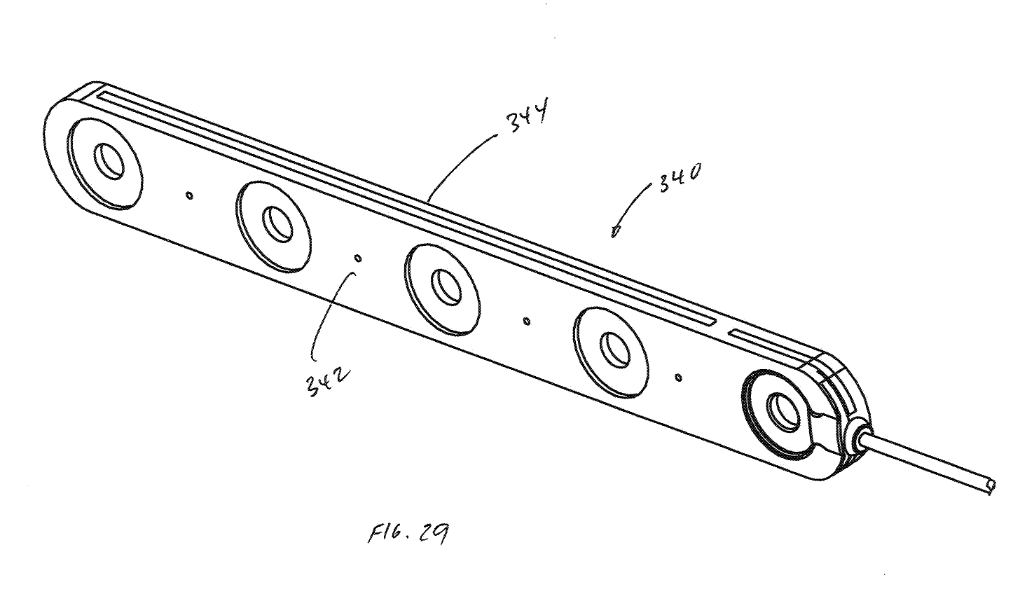

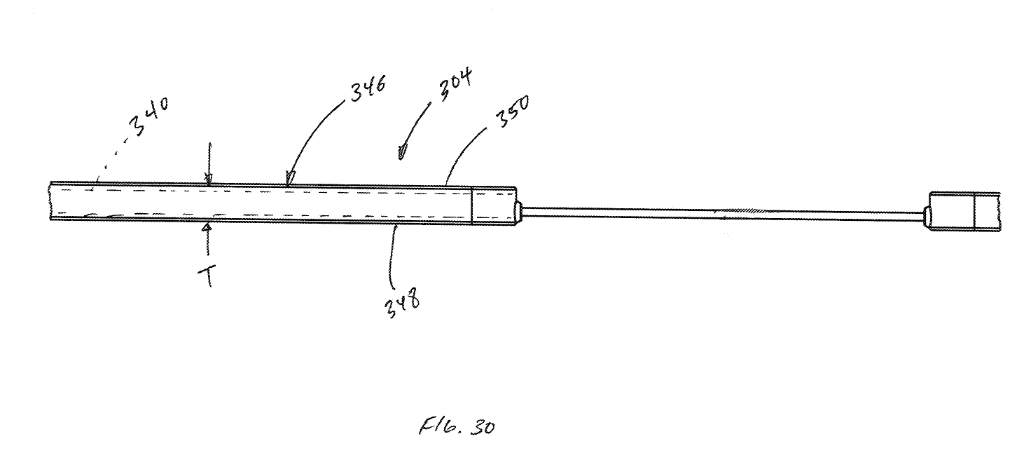

FIG. 28 shows that an inner housing 340 may be formed over the first rigid member 324 and the washer 312. The inner housing 340 may have a first side 342 and a second side 344, which is opposite of the first side 342. The inner housing 340 may be formed so that a centerline 346 of the inner housing 340 and the housing 309 may be substantially aligned. With the overall thickness “t” of the inner housing 340 being less than the thickness “T” of the housing 309, the inner housing 340 may less likely bend the rigid member 324 due to the shrinkage factor of the molded plastic over the first rigid member 324 as the molded plastic cools after the initial injection. FIG. 29 shows a perspective view of the inner housing 340.

FIG. 30 shows an outer housing 346 molded over the inner housing 340 (represented by dotted lines) having a thickness “T” where the outer housing 346 forms the first housing 307 of the first bar 304. The outer housing 346 may have a first surface 348 and a second surface 350. The thickness of the outer housing 346 between the first surfaces 342 and 348 of the inner housing 340 may be similar to the thickness of the outer housing 346 between the first and second surfaces 344 and 346 such that as the plastic mold of the outer housing 346 cools over the inner housing 340, the first and second surfaces 348 and 350 may cool at a substantially similar rate to minimize bending of the inner housing 340 due to the shrinkage factor.

While various embodiments of the invention have been described, it will be apparent to those of ordinary skill in the art that many more embodiments and implementations are possible within the scope of this invention. For instance, the wire 32 and the flexible member 218 may be made of a variety of materials that is flexible such as a metal cable and nylon fabric. The wire 32 and the flexible member 218 may be also a stiff mechanism such as a metal tube or a metal rod to support the pods in a linear manner. Moreover, for larger monitors where the threaded holes are equal or greater than 400 mm apart, more than one wall bracket 12 may be used. Accordingly, the invention is not to be restricted except in light of the attached claims and their equivalents.

What is claimed is:

1. A mount system adapted to attach a monitor to a wall, the mount. system including:
a panel mounting bracket having:
a flexible member between a first washer and a second washer, each of the first and second washers having an opening;
a first rigid member having a first end and a second end, the first end of the first rigid member adapted to couple to the first washer, the first rigid member having a plurality of holes between the first and second ends;
a second rigid member having a first end and a second end, the first end of the second rigid member adapted to couple to the second washer, the second rigid member having a plurality of holes between the first and second ends of the second rigid member; and
a wall plate adapted to couple to the wall, the wall plate having a hook adapted to receive flexible member.

2. The mount system according to claim 1, where each of the first and second rigid members is enclosed by an inner housing.

3. The mount system according to claim 2, where each of the inner housing of the first and second rigid members is enclosed by an outer housing.

4. The mount system according to claim where the first washer has a protruding member, and the first rigid member has an opening adjacent to first end, and the opening on the first rigid member is adapted to receive the protruding member to interlock the first washer to the first rigid member.

5. The mount system according to claim 1, where the first washer has a bonding area adapted to couple to the flexible member, and the bonding area protrudes from the washer along a longitudinal axis of the flexible member.

6. A mount system adapted to attach a monitor to a wall, the monitor having rear side with four VESA holes, the mount system including:
a panel mounting bracket having:
a flexible member between a first washer and a second washer, each of the first and second washers having an opening;
a first bar having a first end and a second end, the first end of the first bar adapted to couple to the first washer, the first bar having a plurality of holes between the first and second ends, the first bar having a first rigid member adapted to couple to the first washer;
a bar having a first end and a second end, the first end of the second bar adapted to couple to the second washer, the second bar having a plurality of holes between the first and second ends of the second bar, the second bar having a second rigid member adapted to couple to the second washer; and
a wall plate adapted to couple to the wall, the wall plate having a hook adapted to receive flexible member.

7. The mount system according to claim 6, where the first rigid member is enclosed by an inner housing, and the inner housing is enclosed by an outer housing.

8. The mount system according to claim 6, where one of the holes in the first bar corresponds with one of the holes in the second bar such that a distance between, the two corresponding holes substantially match a distance between top two VESA holes of the monitor.

9. The mount system according to claim 6, where the first washer has a protruding member, and the first rigid member has an opening adjacent to first end of the first bar, and the opening on the first rigid member is adapted to receive the protruding member to interlock the first washer to the first rigid member.

10. A method of forming a panel mounting bracket, the method including:
bonding a first washer on a first end of a wire;
bonding a second washer on a second end of the wire;
forming a plurality of holes between a first and second ends of a first rigid member;
forming a plurality of holes between a first and second ends of a second rigid member;
coupling the first washer to the first end of the first rigid member; and
coupling the second washer to the first end of the second rigid member.

11. The method according to claim 10, including:
forming an inner housing over the first and second rigid members.

12. The method according to claim 11, including:
forming an outer housing over the inner housing of the first and second member.
